(19) United States
(12) Patent Application Publication
(10) Pub. No.: US 2026/0201557 A1
(43) Pub. Date: Jul. 16, 2026

(54) System and Method for Atomic Layer Etching and Radical-Enhanced Deposition in a Single Process Chamber

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 19/015,664

(22) Filed: Jan. 10, 2025

(51) Int. Cl. C23C 16/455; C23C 16/44; H01J 37/32; H01L 21/02

(52) U.S. Cl. CPC C23C 16/45536; C23C 16/4408; C23C 16/45553; H01J 37/32146; H01J 37/32724; H10P 14/6339; H01J 2237/3323; H01J 2237/3341

(57) ABSTRACT

Disclosed is a plasma process chamber and method for integrating Atomic Layer Etching (ALE) and radical-enhanced deposition, such as RECVD or REALD, within a single chamber. The system features a switchable blocking capacitor to ground the electrostatic chuck (ESC), eliminating the plasma sheath, and employs high-power, short RF pulses to suppress ion bombardment during ALE surface modification and radical-enhanced deposition steps, enabling efficient processing for applications like forming high aspect ratio structures.

### FIELD OF THE INVENTION

The present invention pertains to the field of semiconductor manufacturing, specifically focusing on systems and methods designed to optimize both atomic layer etching (ALE) and radical-enhanced deposition processes within a single process chamber.

### BACKGROUND OF THE INVENTION

Reactive ion etching (RIE) is a predominant technology in semiconductor manufacturing. In RIE, various species, including radicals and ions, concurrently influence the etching process. A key characteristic of RIE is the synergistic interaction between ion and radical fluxes, which significantly enhances the etching rate. This synergistic effect was first described by Coburn and Winters in “Ion- and electron-assisted gas-surface chemistry—an important effect in plasma etching,” published in J. Appl. Phys., vol. 50, pages 3189-3196 (1979). They reported increased silicon etching rates when using an argon ion beam, a XeF₂ neutral beam, and their combination. Effective RIE necessitates the presence of both ion and neutral fluxes to exploit this synergy. However, in modem etching processes, balancing these fluxes, particularly for etching high aspect ratio structures with dimensions shrinking to the nanometer scale, is increasingly complex. Achieving uniform results across 300 mm wafers and consistent repeatability in production pose additional challenges.

ALE has been developed to address the limitations of RIE. The ALE process system has evolved from the RIE process system, with less stringent requirements for achieving uniformity on a 300 mm wafer. However, ALE has unique requirements due to the nature of its process steps. An overview of ALE technology is presented by Karanik et al. in “Overview of atomic layer etching in the semiconductor industry” (J. Vac. Sci. Technol. A33, pages 020802 1-14, 2015) and further discussed by Lill in “Atomic layer processing: semiconductor dry etching technology” (Wiley-VCH GmbH, Boschstr. 12, 69469 Weinheim, Germany, 2021). ALE facilitates the controlled removal of material layers with atomic-level precision and is characterized as an etching technique using sequential self-limiting reactions. The basic ALE process includes two steps: surface modification and material removal. The modification creates a thin reactive layer with a defined thickness, which is easier to remove than the unmodified material. The removal step eliminates this modified layer while preserving the underlying substrate, thus resetting the surface for subsequent cycles. Material removal can be achieved using thermal energy by raising the wafer's temperature or kinetic energy from ions typically derived from inert gases. The isotropic process using thermal energy to remove modified layers is described in U.S. Pat. No. 10,208,383 to George et al. When utilizing energetic ions, the removal is conducted via a sputtering process. The anisotropic ALE process, as described in U.S. Pat. No. 10,727,073 to Tan et al., demonstrates the technology's versatility.

The distinct chemistry, speciation, and plasma energy composition involved in the surface modification and sputtering steps enhance the process by enabling more controlled ion, electron, and neutral species fluxes, thereby widening the process window. This separation facilitates self-limiting reactions, crucial for maintaining the ideality of the etching process—characterized by uniformity, smoothness, and selectivity. Karanik et al., in “Predicting synergy in atomic layer etching” (J. Vac. Sci. Technol. A35, pages 05C302 1-7, 2017), defined ALE synergy as:

$$A L {E}_{s y n e r g y} S ( \% ) = \frac{E P C - ( α + β )}{E P C} \times 100 \% , \qquad [ 1 ]$$

where EPC is “etch per cycle,” representing the total thickness of material removed in one cycle, typically averaged over many cycles. The values of “α” and “β” are (undesirable) contributions from the surface modification step and the sputtering step, respectively. Ideally, synergy will approach 100% with no etching from either step alone. In practice, RIE in the surface modification step is nonzero because of the presence of ions in the plasma, which generates neutrals to modify the surface. In the sputtering step, physical sputtering of the underlying unmodified layer is also nonzero.

It is desirable for the plasma in the surface modification step of the ALE process to be free from ion bombardment. However, the unintended introduction of RIE components during this step presents a persistent challenge. This issue stems from the difficulty in completely preventing ion bombardment of the substrate surface, compromising the ideality of the ALE processes. Modern ALE methodologies struggle to effectively eliminate these RIE components, leading to suboptimal etching outcomes, particularly as device geometries become more complex and smaller in scale. The presence of RIE components in ALE processes can result in non-uniform layer removal and undesirable etching profiles, which are especially problematic in advanced device manufacturing where even minor deviations can significantly impact device performance and yield.

One solution to this problem, as disclosed in U.S. Pat. No. 9,362,131 to Agarwal et al., involves using an electron beam source. During the passivation step (surface modification step), a remote plasma source supplies passivation species to the main process chamber while keeping ion energy below the etching threshold. During the etching operations, the flow from the remote plasma source is stopped, and the ion energy is raised above the etch threshold. This approach introduces an additional remote source, complicating the apparatus and increasing the cost of the process.

Another solution to this problem, as disclosed in U.S. Pat. No. 10,014,192 to Singh, involves using a chamber that is divided into a plasma-generating region and a substrate-processing region by a separating plate structure. This plate structure blocks ions from reaching the substrate while utilizing low-energy metastable species to etch the substrate. However, due to the complete elimination of high-energy ions in the processing region, Singh's method is ineffective for etching high aspect ratio (HAR) structures. In such structures, high-energy ions are essential for reaching the bottom of deep or narrow features. Without sufficient ion energy, the etching process lacks the directional control needed to effectively etch HAR features.

The present invention addresses limitations in plasma-enhanced ALE (PEALE) by introducing systems and methods that eliminate the reactive ion etching (RIE) component during the surface modification step. The terms ALE and PEALE are used interchangeably throughout this disclosure. This is achieved by minimizing ion generation or removing the plasma sheath, aligning with radical-enhanced deposition processes like radical-enhanced atomic layer deposition (REALD) and radical-enhanced chemical vapor deposition (RECVD).

In HAR structures, avoiding ions during deposition is critical to prevent anisotropic deposition, physical sputtering, charge buildup, and structural damage. Ions also struggle to penetrate deep recesses, causing non-uniform coverage. Radical-enhanced deposition processes, by contrast, utilize isotropically diffusing radicals, ensuring uniform deposition along all surfaces. In ALD, these reactions are self-limiting, enabling precise control over layer thickness and conformality, particularly in HAR applications. However, conventional ALD can still struggle with uniformity in HAR structures due to plasma ion energy and angular distribution effects.

Currently, PEALE and radical-enhanced deposition processes are typically conducted in separate chambers. PEALE removes material anisotropically, while REALD or RECVD deposits material isotropically. For HAR applications, such as depositing liners to maintain vertical profiles, these processes often need to be performed sequentially. Transferring substrates between chambers increases complexity, contamination risks, and process time.

While prior methods, such as those disclosed in U.S. Pat. No. 9,805,941 to Karanik et al., integrate ALE and ALD within one chamber, they do not address challenges like ion-free surface modification during ALE or achieving conformal ALD in HAR structures. The invention overcomes these gaps by introducing a unified system and method to enhance the ALE and radical-enhanced deposition processes, ensuring better layer uniformity, reduced contamination risks, and improved efficiency in semiconductor manufacturing.

### SUMMARY

In some embodiments, the present invention provides a system and method for integrating in situ PEALE and REALD/RECVD within a single process chamber. When etching and deposition process steps need to be performed sequentially, this integration significantly simplifies process flow, reduces cycle time, minimizes process costs, and addresses time-sensitive process steps that are critical in advanced semiconductor manufacturing.

In some embodiments, the system leverages the shared requirement of minimizing ion effects during both the ALE surface modification step (step A) and radical-enhanced deposition steps. The surface modification step in ALE, which modifies the substrate surface using reactive radicals without material removal, demands a low-ion or ion-free environment. Similarly, the radical-enhanced deposition steps require a radical-only process to achieve high conformality when depositing along surfaces of HAR structures. In some implementations, the system achieves this by suppressing plasma sheath formation or reducing ion generation during these steps, thereby enhancing process ideality.

In some embodiments, two novel techniques are introduced to reduce ion effects. The first technique employs a switchable blocking capacitor that can be activated or deactivated based on the process step. In some implementations, the blocking capacitor is deactivated during the ALE surface modification step or the radical-enhanced deposition steps, effectively preventing ion bombardment while utilizing generated radicals. The second technique involves using short RF power pulses for the plasma source, where the RF signal is modulated by a square wave with a defined duty cycle less than 10% to limit ion generation. In some implementations, this short RF pulsing technique allows radical-based processing during ion-sensitive steps.

Thus, the present invention provides a system and method that not only optimizes ALE and radical-enhanced deposition processes but also enhances manufacturing efficiency, reduces costs, and ensures compatibility with advanced semiconductor fabrication requirements.

### BRIEF DESCRIPTIONS OF THE DRAWINGS

FIG. 1A: Illustrates an exemplary plasma process chamber in a first embodiment, featuring a switchable blocking capacitor and short RF pulses for the plasma source.

FIG. 1B: Illustrates an exemplary plasma process chamber in a second embodiment, featuring a tailored waveform generator for the proving a chuck's bias voltage selectively using a two-way switch.

FIG. 2: Presents schematic diagrams of exemplary process sequences integrating ALE and radical-enhanced deposition steps.

FIG. 3: Shows a flowchart for integrated ALE and radical-enhanced deposition steps.

FIG. 4: Depicts exemplary operating modes of the plasma process chamber for ALE and radical-enhanced deposition processes.

### DETAILED DESCRIPTIONS

To ensure comprehensive understanding, this section provides detailed embodiments of the present invention. Although specific details are included for clarity, modifications and variations that align with the subsequent claims are considered within the scope of this disclosure.

Conventional methods and components are highlighted to distinguish the invention's unique features.

### Terms Used in This Disclosure

Plasma Process Chamber: A vacuum chamber designed for integrated ALE and radical-enhanced deposition processes.

Chamber Housing: The enclosure of the plasma process chamber, constructed from plasma-resistant materials.

Window: A dielectric barrier that supports plasma generation while maintaining vacuum integrity.

Plasma Source: A component that generates plasma, typically using inductively coupled plasma (ICP) or transformer coupled plasma (TCP).

Gas/precursor Distribution Unit: A system that ensures delivery of process gases or precursors, such as an injector or showerhead.

Controller: A computer that manages process parameters, operations, and transitions between processing steps.

Blocking Capacitor: A device that blocks electrons generated in plasma diffused into the ground and enables plasma sheath formation.

Tailored Waveform Generator: A device that provides custom waveform for generating a chuck's bias, typically for tighter ion energy distribution.

RF Power Generator: A system that supplies and modulates RF power for plasma generation and control.

Surface Modification Step (A): A step in ALE where radicals chemically modify the substrate surface without material removal.

Sputtering Step (B): A step in ALE where inert gas ions remove the modified surface layer via ion bombardment.

Dosing Step (C): A step in radical-enhanced ALD where precursors form a monolayer on the substrate surface.

Radical Activation Step (D): A step in radical-enhanced ALD where radicals react with the precursor monolayer to complete material deposition.

Radical Reactor: A configuration of the chamber optimized for generating radicals with minimal ion bombardment.

ALE (Atomic Layer Etching): A cyclic process that alternates between surface modification and sputtering steps for atomic-scale material removal.

REALD (Radical-Enhanced ALD): A radical-enhanced ALD deposition process used for conformal layer formation.

RECVD (Radical-Enhanced CVD): A radical-enhanced chemical vapor deposition process focused on eliminating effects of ions.

High Aspect Ratio (HAR) Structures: Features with a large height-to-width ratio that require precise etching and deposition techniques.

Conformal Layer: A uniformly deposited material layer critical for achieving desired profiles in HAR applications.

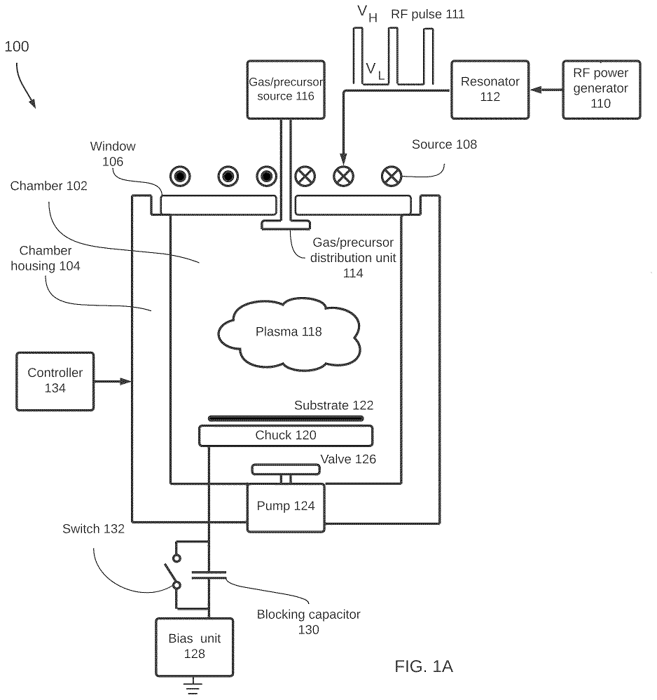

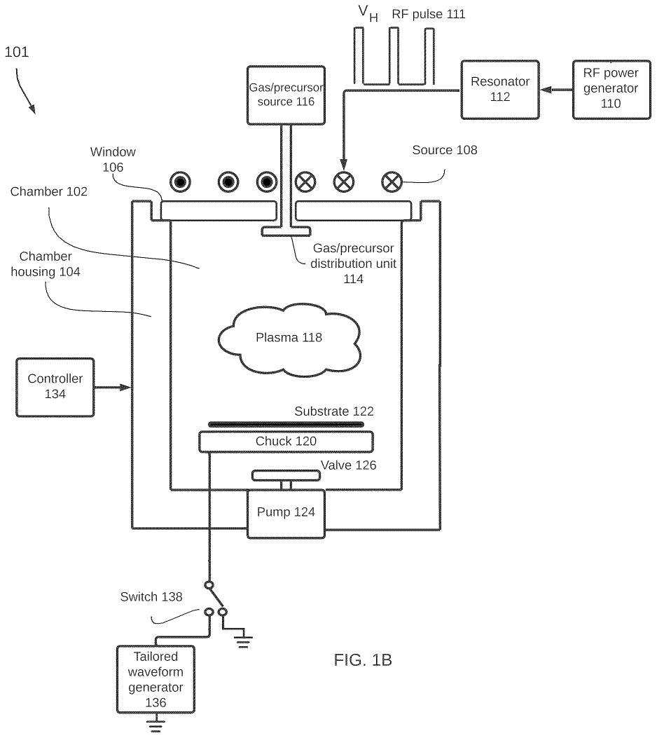

FIG. 1A illustrates an embodiment of a process system, designated as 100, comprising a plasma process chamber, labeled as 102, coordinated by a controller, referred to as 134. The chamber 102 is enclosed by a chamber housing, indicated as 104, which provides a vacuum environment suitable for plasma processing. The housing 104 may be constructed from materials such as aluminum or quartz, with the aluminum surface optionally treated through anodizing or yttrium oxide coating to enhance resistance to plasma exposure.

A hermetically sealed window, labeled as 106, is positioned atop the chamber housing 104. In some embodiments, the window is made of quartz or other plasma-resistant materials, with its interior surface optionally coated with a plasma-resistant material like yttrium oxide. Above the window 106, a plasma source, designated as 108, is situated. The plasma source includes a three-turn coil but may have variations in the number of turns, shapes (e.g., cylindrical or conical), or configurations, depending on operational requirements.

The plasma source 108 is connected to a radio frequency (RF) power generator, labeled as 110, via a resonator, identified as 112, to ensure impedance matching with the plasma load in chamber 102. The RF power generator 110 can operate at single or multiple frequencies, including but not limited to 100 kHz, 200 kHz, 400 kHz, 2 MHz, 13.56 MHz, 27 MHz, 40 MHz, and 60 MHz. In some implementations, the RF power is delivered in a pulsed form, represented as 111, modulated by a square wave with a specified duty cycle. This duty cycle, expressed as a percentage, is defined by high (V_{H}) and low (V_{L}) DC voltage levels, with V_{L} being either ground voltage or nonzero.

In inductively coupled plasma (ICP) or transformer coupled plasma (TCP) reactors, plasma ignition involves a transition from E mode (electrostatic mode) to H mode (helicon or high-density mode). E mode relies on capacitive coupling with low plasma density, while H mode uses inductive coupling for high plasma density and ionization efficiency. During RF pulsing, if the duty cycle or the time at V_{H} is too short, plasma may not be able to achieve the H mode.

Repeated transitions between E mode and H mode increase energy consumption and process inefficiency. Maintaining a minimal sustaining power for plasma staying in the H mode reduces the time and energy needed to re-establish H mode and ensuring consistent plasma characteristics.

To minimize ion generation while maintaining high radical concentrations, short RF pulses 111 can be designed so that the plasma remains “on” at a minimal RF power. This configuration allows the RF power to rapidly achieve the desired high-power state without repeated E-to-H transitions. Combining this technique with a switchable blocking capacitor ensures ion-free or low-ion plasma conditions for processes like the ALE surface modification step and radical-enhanced deposition processes, where a high radical concentration and minimal ion energy are critical.

A gas/precursor distribution unit, labeled as 114, connects to a gas/precursor source, identified as 116, via an aperture in the window 106, ensuring a hermetic seal. The gas/precursor source 116 may supply various process gases, and the distribution unit 114 may function as an injector or showerhead. In some configurations, the window 106 integrates the gas/precursor distribution unit 114 as a showerhead.

Within the chamber 102, a chuck, labeled as 120, supports a substrate, indicated as 122. The chuck 120 may be an electrostatic chuck (ESC) or vacuum chuck. The chamber 102 is coupled to a pump, labeled as 124, and an associated valve, labeled as 126, to remove unused gases and reaction byproducts, with the withdrawal rate controlled by the valve 126 and pump 124 capacity.

A blocking capacitor, labeled as 130, is included to block direct current (DC) signals, stabilizing the plasma sheath above the substrate 122. This capacitor prevents electron movement to the ground, enabling the accumulation of a negative potential. A parallel switch, labeled as 132, connected to the blocking capacitor 130, allows dynamic control. When the switch 132 is closed, the chuck 120 is grounded via the bias unit 128. When open, the blocking capacitor 130 functions normally. In other configurations, a two-way or series switch may connect the chuck 120 to either ground or the bias unit 128.

During the ALE surface modification step, the switch 132 bypasses the blocking capacitor 130, preventing sheath formation and eliminating reactive ion etching (RIE). In the sputtering step, the switch 132 is open, activating the blocking capacitor 130 to establish a bias for ion acceleration. The controller 134 manages the switch operation via electrical signals, and the switch 132 may include transistors or relays, such as power MOSFETs, or other known mechanisms.

FIG. 1B illustrates another embodiment, designated as 101, in which a tailored waveform generator, labeled as 136, provides a bias for the chuck 120. The tailored waveform generator 136 facilitates tighter ion energy distribution, which is critical for advanced etching processes, particularly for the formation of HAR structures. The tailored waveform generator 136 typically operates at a significantly lower frequency compared to the RF power generator used for the plasma source. Unlike other configurations, the operation of the tailored waveform generator 136 may not require a blocking capacitor.

In this embodiment, a two-way switch, labeled as 138, is employed to deactivate the tailored waveform generator 136 during the surface modification step by grounding the chuck 120.

During the sputtering step, the switch 138 activates the tailored waveform generator 136, enabling precise control over the ion acceleration.

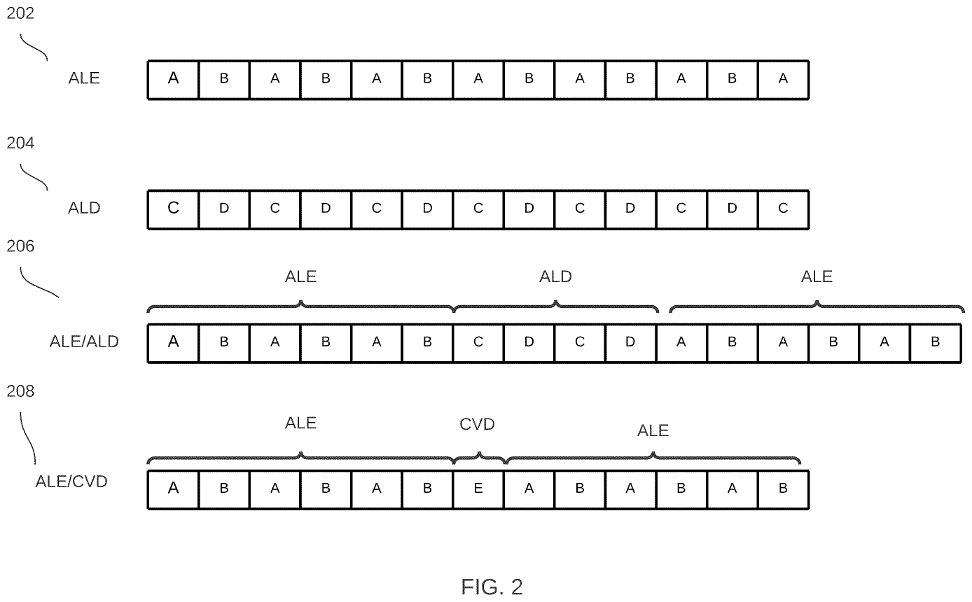

FIG. 2 illustrates four exemplary process sequences of the process system 100. The first mode is the ALE-only operating mode, denoted as 202. ALE is a cyclic process consisting of multiple cycles, each involving a surface modification step (A) and a sputtering step (B). Similarly, the REALD-only process is denoted as 204, which is also cyclic, comprising a dosing step (C) and a radical activation step (D).

In many semiconductor manufacturing applications, ALE and ALD processes can be synergistically integrated to optimize performance. For instance, in advanced processes, an ALD process can be used to deposit a thin, conformal layer to adjust the critical dimension of an opening, such as a trench or a hole, after an ALE process is used to etch a layer. In another scenario, particularly in the formation of high aspect ratio structures, an ALD process can deposit a sidewall-protecting layer following an ALE etching step. Additionally, ALE can enhance the gap-fill capabilities of ALD in high aspect ratio openings.

The combined ALE and ALD process, illustrated as 206 in FIG. 2, can result in either net deposition or net etching, depending on the application. Consequently, the combined process may begin or end with either an ALE or ALD process. The ALE and ALD processes within sequence 206 are referred to as phases, and the number of cycles in the ALE and ALD phases can be adjusted based on specific application requirements.

During the sputtering step (B) of the ALE process, the bias unit 128 or the tailored waveform generator 136 provides a bias voltage to the chuck 120. An inert gas, such as argon, is injected into the plasma process chamber 102, where an argon plasma 314 is generated. Positive argon ions are accelerated by the bias voltage, propelling them toward the substrate 122 and removing the modified surface layer.

In the REALD process, steps C and D are conducted sequentially, similar to ALE. During the dosing step (C), a precursor is introduced into the chamber 102 and adsorbs onto the substrate's surface, forming a monolayer. This step may be followed by a gas purge to remove excess precursor. In the subsequent radical activation step (D), the substrate is exposed to radicals, which react with the precursor monolayer, forming the desired film on the substrate.

The innovative design of the process system 100, as illustrated in FIGS. 1A and 1B, enables efficient execution of both ALE and REALD processes.

In another exemplary process sequence, denoted as 208, the REALD process may be replaced by a RECVD process, referred to as step (E). In some applications, such as depositing a liner for high aspect ratio structures on the top surface and sidewalls, RECVD may be employed.

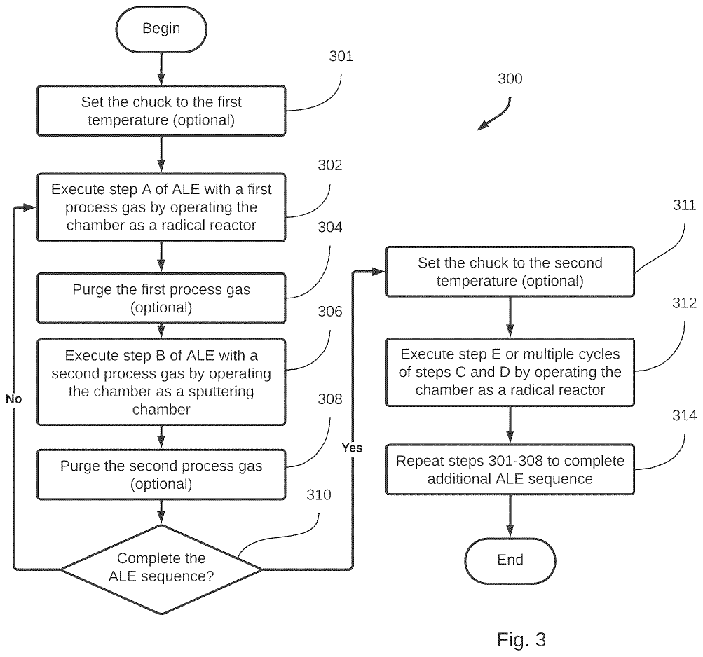

FIG. 3 presents a flowchart for an in situ atomic layer etching and radical-enhanced deposition process, labeled as 300.

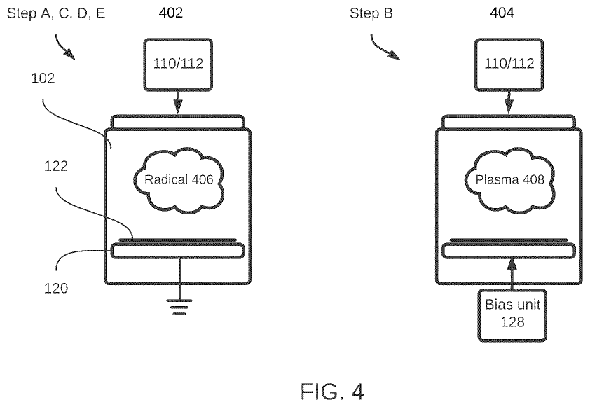

The process begins with step 301, where the chuck 120 is set to a first temperature suitable for the ALE process, typically ranging from −30° C. to 150° C. In step 302, the ALE surface modification step (step A) is performed within the plasma process chamber 102, operating as a radical reactor 402 with radicals 406, as shown in FIG. 4. A first process gas is introduced into the chamber 102 via the gas and precursor distribution unit 114. During step A, ions and radicals are generated, with ion effects minimized. In one implementation, the blocking capacitor 132 is deactivated. In another, RF power pulses 111 with a very low duty cycle (e.g., less than 10%) are applied. In some cases, the duty cycle may be below 1%. These approaches can also be combined for optimal performance. During step A, the substrate surface is chemically modified without material removal. For example, in a silicon ALE process, chlorine gas introduced into the chamber generates a chlorine plasma containing radicals. These radicals react with the substrate surface, forming silicon-chlorine bonds that weaken the underlying silicon bonds, preparing the material for removal in step B.

In step 304, the first process gas is optionally evacuated from the chamber using a purging gas like nitrogen. In step 306, the sputtering step (step B) is executed by operating the plasma process chamber 102 as a sputtering chamber 404, shown in FIG. 4, with plasma 408. In one embodiment, the blocking capacitor 132 is activated to establish a bias for ion acceleration. In another embodiment, the tailored waveform generator 136 is utilized to accelerate ions, ensuring a tighter ion energy distribution. A second process gas, typically an inert gas like argon, is introduced during step B. In step 308, the second process gas is optionally purged using a gas like nitrogen. In step 310, the controller 134 checks whether the ALE sequence are complete. If not, steps 302 to 308 are repeated until the required number of cycles is completed. Once complete, the controller transitions to step 311.

In step 311, the controller sets the chuck 120 to a second temperature, typically higher than the first. For radical-enhanced deposition processes, this temperature may range from room temperature to several hundred degrees Celsius, or even cryogenic temperatures in certain cases.

In step 312, step (E) or multiple cycles of steps C and D are executed to deposit a layer of material, such as oxide, nitride, or carbon. During this step, the plasma process chamber 102 operates as the radical reactor 402, as shown in FIG. 4. In step 314, additional ALE sequence may be executed by repeating steps 301 to 308 if required.

1. A plasma process chamber for performing in situ ALE and radical-enhanced deposition processes, comprising:
a plasma source connected to an RF power generator, configured to generate a plasma within the chamber;
a chuck configured to support a substrate;
a bias unit operatively connected to the chuck, configured to generate a bias voltage for accelerating ions during a sputtering step of the ALE process;
a gas/precursor distribution unit configured to deliver process gases and/or precursors;
a controller configured to:
operate the chamber in a surface modification step of an ALE process, wherein the plasma is ignited by the plasma source, and the chamber is configured to suppress ion bombardment;
operate the plasma process chamber in a sputtering step of the ALE process, wherein ions are accelerated by the bias unit to remove the modified layer; and
operate the plasma process chamber in a radical-enhanced deposition step, wherein the chamber is configured to suppress ion bombardment.

2. The chamber of claim 1, wherein the radical-enhanced deposition step comprises an REALD or an RECVD step.

3. The chamber of claim 1, wherein the ion bombardment are suppressed by configuring a switchable blocking capacitor, and the blocking capacitor is deactivated during the surface modification and the radical-enhanced deposition step.

4. The chamber of claim 1, wherein the ion bombardment are suppressed by applying pulsed RF power to the plasma source.

5. The chamber of claim 4, wherein the pulsed RF power alternates between a high RF power state and a low RF power state.

6. The chamber of claim 5, wherein the low RF power state corresponds to zero RF power.

7. The chamber of claim 5, wherein the low RF power state corresponds to a non-zero RF power, designed to be as low as possible while sustaining the plasma.

8. The chamber of claim 4, wherein the duty cycle of the pulsed RF power is below 10%.

9. The chamber of claim 1, wherein the ALE process is performed in cycles, and the radical-enhanced deposition step is inserted within a sequence of ALE cycles.

10. The chamber of claim 1, wherein the radical-enhanced deposition step is employed to deposit a liner between two ALE sequences for etching an HAR structure.

11. The chamber of claim 1, wherein the controller executes a purging step between a gas or a precursor transition step.

12. A method for conducting an ALE process and a radical-enhanced deposition process in a single process chamber, comprising:
a) providing a process system including a plasma process chamber, a plasma source coupled to an RF power generator, a gas/precursor source, a gas/precursor distribution unit, a chuck, a bias unit, and a controller;
b) setting by the controller the chuck to a first temperature;
c) executing by the controller a surface modification step of an ALE cycle, wherein the chamber is operated as a radical reactor with suppressed ion bombardment;
d) executing by the controller a sputtering step of the ALE cycle, wherein the chamber is operated as a sputtering chamber;
e) repeating steps c) and d) until a first ALE sequence is completed;
f) setting by the controller the chuck to a second temperature;
g) executing by the controller a radical-enhanced deposition step; and
h) repeating steps c) and d) until a second ALE sequence is completed.

13. The method of claim 12, wherein radical-enhanced deposition step comprises an REALD, including a dosing step and a radical activation step.

14. The method of claim 12, wherein radical-enhanced deposition step comprises a RECVD step.

15. The method of claim 12, wherein the surface modification step and the radical-enhanced deposition step are executed by operating the chamber as a radical reactor with a first and a second technique to suppress the ion bombardment.

16. The method of claim 15, wherein the first technique comprises deactivating a blocking capacitor while the chamber is operated as the radical reactor.

17. The method of claim 12, wherein the second technique comprises applying pulsed RF power alternates between a high RF power state and a low RF power state.

18. The chamber of claim 17, wherein the low RF power state corresponds to zero RF power.

19. The chamber of claim 17, wherein the low RF power state corresponds to a non-zero RF power, designed as low as possible while sustaining the plasma.

20. The chamber of claim 17, wherein the duty cycle of the pulsed RF power is below 10%.
